(19) United States
(12) Patent Application Publication
(10) Pub. No.: US 2004/0095152 A1
(43) Pub. Date: May 20, 2004

(54) Power saving apparatus circuit and method

(76) Inventor: Tsang Ho, ShenZhen (CN)

Correspondence Address: Stephen M. De Klerk, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/295,966

(22) Filed: Nov. 14, 2002

(51) Int. Cl. G01R 27/26

(52) U.S. Cl. 324/686

(57) ABSTRACT

Apparatus for determining whether or not an electrically powered device is to be in a normal operational mode or a reduced power operational mode, the apparatus including detection means for detecting the presence or otherwise of a virtual capacitance represented by a part of a human body, and switching means to switch the device between modes depending on the result of the detection means. The detection means includes at least one electrically conductive region and at least one detection terminal, the detection terminal being part of a detection circuit. There is one detection terminal for each electrically conductive region. The detection circuit includes a first transistor for receiving an oscillation pulse, a second transistor also for receiving the oscillation pulse and being controlled by the first transistor, the first transistor having an output that is above a threshold voltage in the absence of the virtual capacitance and that is below the threshold voltage in the presence of the virtual capacitance, the second transistor having an oscillation output as an input to the switching means. A plurality of resistors determines the threshold voltage. The device requires the presence of at least one part of the human body for at lest one operational function of the device.

### FIELD OF THE INVENTION

This invention relates of a power saving apparatus, circuit and method and refers particularly, though not exclusively, to such a power saving apparatus, circuit and method for use with devices where at least a part of the human body such as, for example, a human hand, is required for at least partial functionality.

### BACKGROUND TO THE INVENTION

There are many electrically powered devices that use a power saving mode to reduce power consumption, particularly when not in use. For example, computer monitors, television receivers, stereo amplifiers, and apparatus for reproducing picture and/or sound (VCR, DVD, CD, VCD etc players and/or recorders). Most of these use a clock system to move to the power saving mode—no operational instructions have been received for a preset time. To move to the normal mode requires a positive action such as an instruction by pushing a button or key, moving a computer mouse, or the like.

This particularly applies to battery powered devices such as, for example, wireless devices including a computer keyboard; a computer mouse; a mobile (cell/hand) telephone; a cordless telephone; a telephone handset; a remote controls for a devices such as, for example, air conditioning, television receiver, radio, media player (DVD, VCD, VCR etc); dictating machines, and so forth.

The human body is a very large capacitor. Provided the current is sufficiently low, the human body can easily store electrical energy. The “zap” sometime felt when contacting a metal door handle or the like is a good example of this.

Therefore, for a device requiring hand contact for operation, the presence or otherwise of a part of the human body may be able to be detected due the inherent capacitance of the human body.

It is therefore the principal object of the present invention to provide a power saving apparatus, circuit and method where the human body capacitance is used as the primary “trigger”.

### SUMMARY OF THE INVENTION

With the above and other objects in mind the present invention provides apparatus for determining whether an electrically powered device is to be in a normal operational mode or a reduced power operational mode, the apparatus including detection means for detecting the presence or otherwise of a virtual capacitance represented by a part of a human body, and switching means to switch the device between modes depending on the result of the detection means.

The detection means may include at least one electrically conductive region and at least one detection terminal, the detection terminal being part of a detection circuit. There may be one detection terminal for each electrically conductive region. Each electrically conductive region may be made of conductive silicon rubber. The switching means may be a micro control unit.

The detection circuit may include a first transistor for receiving an oscillation pulse, a second transistor also for receiving the oscillation pulse and being controlled by the first transistor, the first transistor having an output that is above a threshold voltage in the absence of the virtual capacitance and that is below the threshold voltage in the presence of the virtual capacitance, the second transistor having an oscillation output as an input to the switching means.

The device may require the presence of at least one part of the human body for at lest one operational function of the device.

The present invention also provides a detection circuit including a first transistor for receiving an oscillation pulse, a second transistor also for receiving the oscillation pulse and being controlled by the first transistor, the first transistor having an output that is above a threshold voltage in the absence of the virtual capacitance and that is below the threshold voltage in the presence of the virtual capacitance, the second transistor having an oscillation output as an input to the switching means.

There may be a plurality of resistors the value of which determines the threshold voltage. The threshold voltage may be at least equal to a base voltage to turn on the second transistor; and the virtual capacitance may be at least a part of a human body.

The present invention also provides a method for switching a device between a normal operation mode and a power reduction mode, the method including the steps of detecting the presence or otherwise of a virtual capacitance represented by a part of a human body, and switching the device between modes depending on the result of the detection means.

The detection may be by at least one electrically conductive region and at least one detection terminal, the detection terminal being part of a detection circuit. There may be one detection terminal for each electrically conductive region; and each electrically conductive region may be made of conductive silicon rubber. The switching means may be a micro control unit.

The detection may employ a detection circuit including a first transistor for receiving an oscillation pulse, a second transistor also for receiving the oscillation pulse and being controlled by the first transistor, the first transistor having an output that is above a threshold voltage in the absence of the virtual capacitance and that is below the threshold voltage in the presence of the virtual capacitance, the second transistor having an oscillation output as an input to the switching means.

The device may be selected from the group consisting of any device where human contact is required for at least partial operation including, but is limited to: a computer mouse, a computer keyboard, mobile telephone, hand telephone, cell telephone, cordless telephone, telephone handset, remote control, dictating machine, kitchen appliance, on/off or other switch, and calculator. The device maybe battery powered or may have power supplied to it from an external source.

### DESCRIPTION OF THE DRAWINGS

In order that invention may be clearly understood and readily put into practical effect, there shall now be described by way of non-limitative example only a preferred embodiment of the present invention, the description being with reference to the accompanying illustrative drawings—in which:

FIG. 1 is a partial perspective view of an example of device using a preferred embodiment of the present invention;

FIG. 2 is a flow chart of the operation of the preferred embodiment; and

FIG. 3 is an example of a circuit for performing the method, and for use in the apparatus, of the preferred embodiment.

### DESCRIPTION OF PREFERRED EMBODIMENT

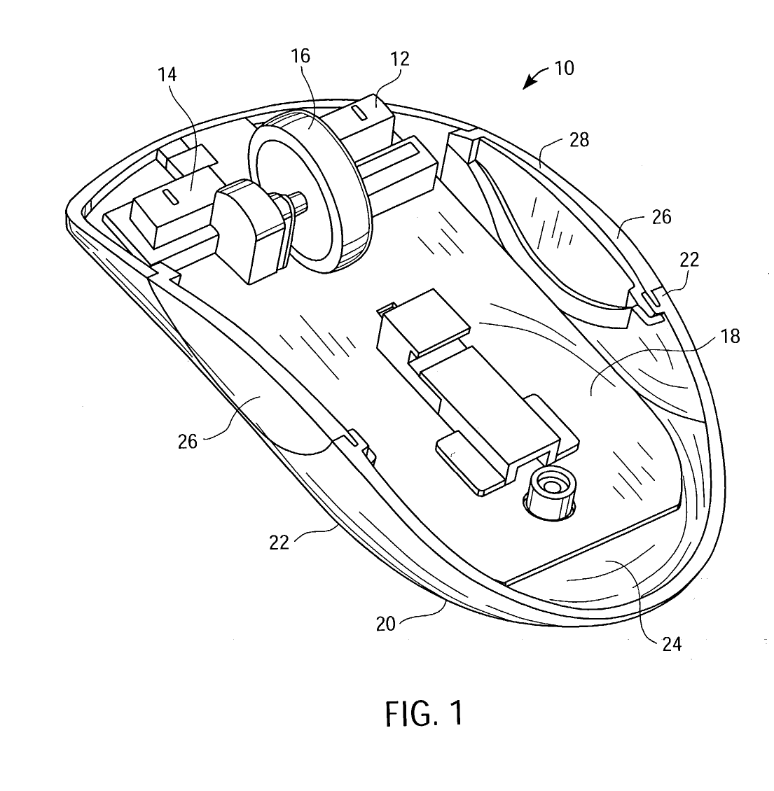

To refer to FIG. 1, there is shown in partial perspective view a computer mouse 10 fitted with the preferred embodiment of the present invention.

The mouse 10 has functional controls 12, 14 for the right and left buttons, a scrolling wheel 16 and a printed circuit board 18. These are all mounted within a casing 20. The casing 20 has a two side walls 22 and a base 24. A cover (not shown) is used to complete the mouse 10.

The casing has at least one conductive region 26. As shown, there are two conductive regions 26. One in each side wall 22 where the mouse 10 would normally be contacted by a human hand—the thumb and fingers in this instance. The region 26 may be at any location on the mouse 10 where they can or should be easily contacted by a human hand. The regions 26 are made of an electrically conductive material such as, for example, conductive silicon rubber, conductive metal, or the like.

Mounted on printed circuit board 18 are two detector terminals 28— one for each region 26. The terminals 28 may contact the internal surfaces of region 26, but are not required to do so. The terminals 28 detect the presence of human body presence by contact or otherwise at one or both of regions 26.

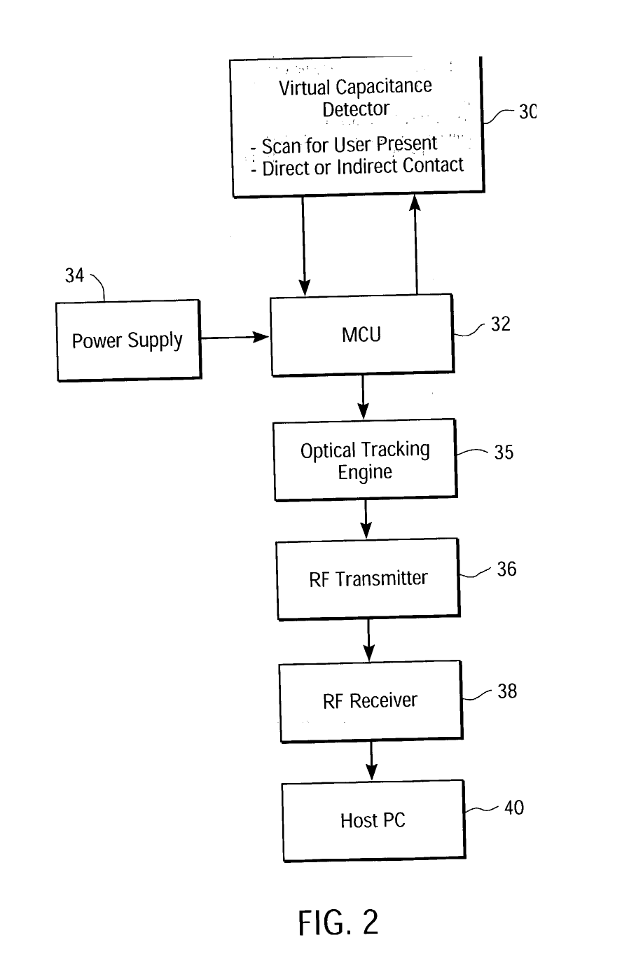

The terminals 28 form part of a vertical capacitance detector—the capacitance of the human body being a “virtual capacitance”. In FIG. 2, the virtual capacitance detector 30 interacts with a micro control unit such as a mouse control unit 32 of the mouse 10. A power supply 34 supplies electrical power to mouse control unit 32. The mouse control unit 32 also controls the operating of an optical tracking engine 35 (for an optical mouse), and the radio frequency transmitters 36 and receives 38 for a wireless mouse. These interact with the host computer 40.

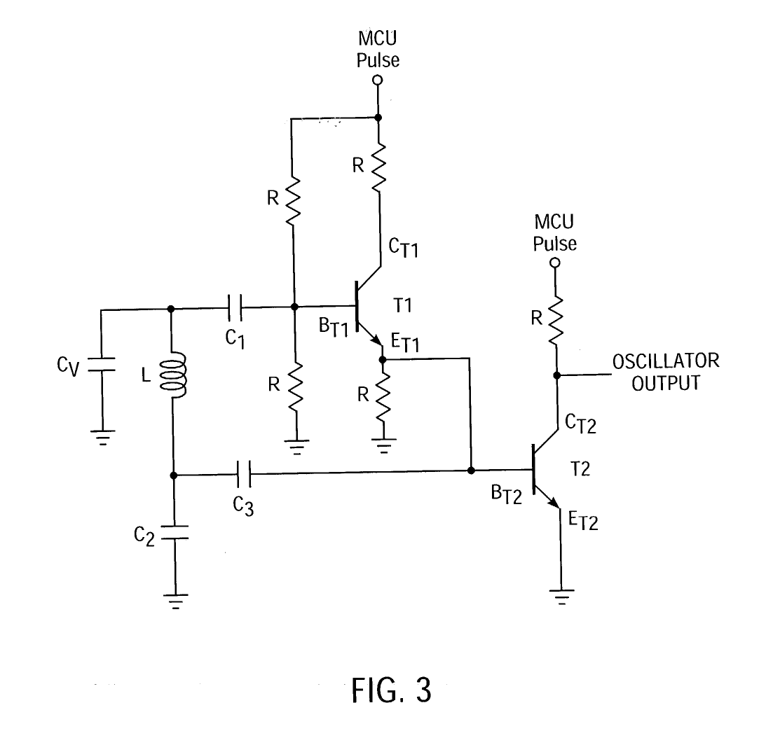

One form of capacitance detector 30 is shown in FIG. 3. Here, there are two NPN transistors T₁ and T₂, each of which is connected to a source of a pulse. The pulse is preferably a 3V pulse of 1 mS per 40 mS cycle at, for example, 8 MHz.

When there is no virtual capacitor Cv present (i.e. no human presence or contact at or adjacent region 26), transistor T₁ forms an oscillation circuit with base BT₂ of transistor T₂. By selecting the values of resistors R, the pulse at BT₂ can be just above a threshold voltage for BT₂ to remain “on”. This threshold voltage may be, for example, 0.45V. As a result of BT₂ remaining “on”, the oscillator output at CT₂ will be detected as logic low (i.e. OV). The device is therefore in standby or power saving mode.

When a part of the human body is at, on or close to regions 26, the terminals 28 detect the presence of a part of the human body and thus Cv is “present”. The pulse signal is absorbed by the virtual capacitor Cv—the human body. In consequence, the oscillation signal voltage at T₁ drops below the threshold voltage and thus base BT₂ of transistor T₂ will be “off”. The oscillator output of transistor T₂ at CT₂ will therefore at the source voltage (3V.) and will be logic voltage high. This is the active mode and thus the mouse control unit 32 will be in a normal or powered operation mode. The mouse 10 resumes normal operation. The oscillator may stop oscillating at this time, if desired.

Whilst in normal operation mode, the mouse control unit 32 will periodically scan for presence of X-Y coordinate processing and/or button operation and/or scroll operation. The period may be for example, every 2 mS. If none of these three activities are present, the mouse control unit 32 will scan the oscillator output CT₂ for logic low (i.e. OV.). If CT₂ is at logic low, the mouse control unit 32 will move the mouse to power save mode. If CT₂ is logic high (i.e. 3V), the mouse control unit 32 will have the mouse 10 remain in normal operational mode or transfer the mouse 10 to normal operational mode if in power saving mode.

If the mouse control unit 32 detects a logic high at oscillator output CT₂ or any one of the functional features of mouse 10, the mouse 10 will be in or be transferred to the normal operation mode.

For devices other than a computer mouse, the functional features maybe from the pressing of a key (e.g. computer keyboard), button (e.g. remote control button), and so forth; or a functional control (e.g. mobile telephone, dictating machine, telephone handset and so forth).

Either or both of the regions 26 do not need to be physically contacted by a part of the human body and the presence of the virtual capacitance can be detected before contact is made. This may also apply if, for example, there is an intervening material such as a glove worn by a user.

The part of the human body used maybe any part such as, for example, hand, foot, face, arm, and so forth. The device may be any device where human contact is required for at least partial operation. This includes, but is not limited to a computer mouse, computer keyboard, mobile telephone, hand telephone, cell telephone, cordless telephone, telephone handset, remote control, dictating machine, kitchen appliances, on/off or other switch, and so forth. The device maybe battery powered or may have power supplied to it from an external source.

Whilst there has been described in the foregoing description a preferred embodiment of the present invention, it will be understood by those skilled in the technology that many variations a modifications in details of design, construction and methods of operation may be made without departing from the present invention.

The present invention extends to all features disclosed both individually and in all possible permutations and combination.

What is claimed:

1. Apparatus for determining whether an electrically powered device is to be in a normal operational mode or a reduced power operational mode, the apparatus including detection means for detecting the presence or otherwise of a virtual capacitance represented by a part of a human body, and switching means to switch the device between modes depending on the result of the detection means.

2. Apparatus as claimed in claim 1, wherein the detection means includes at least one electrically conductive region and at least one detection terminal, the detection terminal being part of a detection circuit.

3. Apparatus as claimed in claim 2, wherein there is one detection terminal for each electrically conductive region.

4. Apparatus as claimed in claim 2, wherein each electrically conductive region is made of conductive silicon rubber.

5. Apparatus as claimed in claim 1, wherein the switching means is a micro control unit.

6. Apparatus as claimed in claim 2, wherein the detection circuit includes a first transistor for receiving an oscillation pulse, a second transistor also for receiving the oscillation pulse and being controlled by the first transistor, the first transistor having an output that is above a threshold voltage in the absence of the virtual capacitance and that is below the threshold voltage in the presence of the virtual capacitance, the second transistor having an oscillation output as an input to the switching means.

7. Apparatus as claimed in claim 6, further including a plurality of resistors the value of which determines the threshold voltage.

8. Apparatus as claimed in claim 6, wherein the threshold voltage is at least equal to a base voltage to turn on the second transistor.

9. Apparatus as claimed in claim 1, wherein the device requires the presence of at least one part of the human body for at lest one operational function of the device.

10. A detection circuit for detecting the presence or otherwise of a virtual capacitance, the detection circuit including a first transistor for receiving an oscillation pulse, a second transistor also for receiving the oscillation pulse and being controlled by the first transistor, the first transistor having an output that is above a threshold voltage in the absence of the virtual capacitance and that is below the threshold voltage in the presence of the virtual capacitance, the second transistor having an oscillation output as an input to the switching means.

11. A detection circuit as claimed in claim 10, further including a plurality of resistors the value of which determines the threshold voltage.

12. A detection circuit as claimed in claim 11, wherein the threshold voltage is at least equal to a base voltage to turn on the second transistor.

13. A detection circuit as claimed in claim 10, wherein the virtual capacitance is at least a part of a human body.

14. A method for switching a device between a normal operation mode and a power reduction mode, the method including the steps of: detecting the presence or otherwise of a virtual capacitance represented by a part of a human body, and switching the device between modes depending on the result of the detection.

15. A method as claimed in claim 14, wherein the detection is by the use of at least one electrically conductive region and at least one detection terminal, the detection terminal being part of a detection circuit.

16. A method as claimed in claim 15, wherein there is one detection terminal for each electrically conductive region.

17. A method as claimed in claim 15, wherein each electrically conductive region is made of conductive silicon rubber.

18. A method as claimed in claim 14, wherein the switching is by us of a micro control unit.

19. A method as claimed in claim 14, wherein the detection is by use of a detection circuit that includes a first transistor for receiving an oscillation pulse, a second transistor also for receiving the oscillation pulse and being controlled by the first transistor, the first transistor having an output that is above a threshold voltage in the absence of the virtual capacitance and that is below the threshold voltage in the presence of the virtual capacitance, the second transistor having an oscillation output as an input to the switching means.

20. A method circuit as claimed in claim 19, wherein the detection circuit further includes a plurality of resistors the value of which determines the threshold voltage.

21. A method as claimed in claim 19, wherein the threshold voltage is at least equal to a base voltage to turn on the second transistor.

22. A method as claimed in claim 14, wherein the device requires the presence of at least one part of the human body for at lest one operational function of the device.

23. A method as claimed in claim 14, wherein the device is selected from the group consisting of: a device where human contact is required for at least partial operation, a computer mouse, a computer keyboard, mobile telephone, hand telephone, cell telephone, cordless telephone, telephone handset, remote control, dictating machine, kitchen appliance, on/off or other switch, and calculator.

24. A method as claimed in claim 23, wherein the device is battery powered.

25. Apparatus as claimed in claim 1, wherein the device is selected from the group consisting of: any device where human contact is required for at least partial operation, a computer mouse, a computer keyboard, mobile telephone, hand telephone, cell telephone, cordless telephone, telephone handset, remote control, dictating machine, kitchen appliances, on/off or other switch, and calculator.

26. Apparatus as claimed in claim 25, wherein the device is battery powered.

27. A detection circuit as claimed in claim 10, wherein the device is selected from the group consisting: any device where human contact is required for at least partial operation, a computer mouse, a computer keyboard, mobile telephone, hand telephone, cell telephone, cordless telephone, telephone handset, remote control, dictating machine, kitchen appliances, on/off or other switch, and a calculator.

28. A detection circuit as claimed in claim 27, wherein the device is battery powered.
